(19) United States
(12) Patent Application Publication
(10) Pub. No.: US 2024/0363662 A1
(43) Pub. Date: Oct. 31, 2024

(54) IMAGE SENSOR AND METHOD OF FABRICATING THE SAME

(71) Applicant: Samsung Electronics Co., Ltd., Suwon-si (KR)

(72) Inventor: Kook Tae KIM, Suwon-si (KR)

(73) Assignee: Samsung Electronics Co., Ltd., Suwon-si (KR)

(21) Appl. No.: 18/389,018

(22) Filed: Nov. 13, 2023

(30) Foreign Application Priority Data
Apr. 26, 2023 (KR) 10-2023-0054658

(51) Int. Cl. H01L 27/146

(52) U.S. Cl. CPC H01L 27/1463; H01L 27/14636; H01L 27/14685

(57) ABSTRACT

Disclosed is an image sensor and a fabrication method. The image sensor comprises a substrate having a first surface and a second surface that are opposite to each other, an antireflection layer on the second surface of the substrate, and a pixel isolation part in the substrate and separating a plurality of pixels from each other. The pixels include first to fourth pixels. The pixel isolation part includes a first part between the first pixel and the third pixel and a second part between the first pixel and the second pixel. Each of the first part and the second part includes a semiconductor pattern that penetrates the substrate along a direction perpendicular to the first surface, a first isolation dielectric pattern between the substrate and the semiconductor pattern, and a capping pattern in the semiconductor pattern. The capping pattern is in contact with the antireflection layer.

### CROSS-REFERENCE TO RELATED APPLICATION

This U.S. nonprovisional application claims priority under 35 U.S.C § 119 to Korean Patent Application No. 10-2023-0054658 filed on Apr. 26, 2023 in the Korean Intellectual Property Office, the disclosure of which is hereby incorporated by reference in its entirety.

### BACKGROUND

Embodiments are related to an image sensor and a method of fabricating the same, and more particularly, to a complementary metal oxide semiconductor (CMOS) image sensor and a method of fabricating the same.

An image sensor is a semiconductor device to transforms optical images into electrical signals. Recent advances in computer and communication industries have led to strong demands in high performances image sensors in various consumer electronic devices such as digital cameras, camcorders, PCSs (Personal Communication Systems), game devices, security cameras, medical micro cameras, etc. An image sensor can be classified into a charge coupled device (CCD) type and a complementary metal oxide semiconductor (CMOS) type. A CMOS type image sensor is abbreviated to CIS (CMOS image sensor). The CIS has a plurality of two-dimensionally arranged pixels. Each of the pixels includes a photodiode (PD). The photodiode serves to transform an incident light into an electrical signal. The plurality of pixels are defined by a deep isolation pattern disposed therebetween.

### SUMMARY

Some embodiments provide an image sensor whose reliability is improved.

Some embodiments provide a method of fabricating an image sensor with increased yield.

Embodiments are not limited to those mentioned above, and other objects which have not been mentioned above will be clearly understood to those skilled in the art from the following description.

According to some embodiments, an image sensor may comprise: a substrate having a first surface and a second surface that are opposite to each other; an antireflection layer on the second surface of the substrate; and a pixel isolation part in the substrate, the pixel isolation part separating a plurality of pixels from each other. The plurality of pixels comprises a first pixel, a second pixel, a third pixel and a fourth pixel arranged along a clockwise direction. The pixel isolation part may include: a first part between the first pixel and the third pixel; and a second part between a center of the first pixel and a center of the second pixel. Each of the first part and the second part may include: a semiconductor pattern that penetrates the substrate along a direction perpendicular to the first surface; a first isolation dielectric pattern between the substrate and the semiconductor pattern; and a capping pattern in the semiconductor pattern. The capping pattern may be in contact with the antireflection layer.

According to some embodiments, an image sensor may comprise: a substrate having a first surface and a second surface that are opposite to each other; an antireflection layer on the second surface of the substrate; and a pixel isolation part in the substrate, the pixel isolation part separating a plurality of pixels from each other. The plurality of pixels comprises a first pixel, a second pixel, a third pixel and a fourth pixel arranged along a clockwise direction. The pixel isolation part may include a first part between a center of the first pixel and a center of the second pixel. The first part may include: a dielectric pattern that penetrates the substrate along a direction perpendicular to the first surface, wherein the dielectric pattern includes a first dielectric pattern adjacent to the second surface and a buried dielectric pattern adjacent to the first surface; a first isolation dielectric pattern between the substrate and the dielectric pattern; a first semiconductor pattern between the first isolation dielectric pattern and the first dielectric pattern; and a capping pattern in the first dielectric pattern. The capping pattern may be between the antireflection layer and the first dielectric pattern.

According to some embodiments of the present inventive concepts, a method of fabricating an image sensor may comprise: preparing a substrate having a first surface and a second surface that are opposite to each other; forming a deep trench that extends from the first surface into the substrate; forming a first isolation dielectric layer that covers an inner wall of the deep trench; forming a first semiconductor pattern that conformally covers the first isolation dielectric layer in the deep trench; forming a second semiconductor pattern that fills a portion of the deep trench, the second semiconductor pattern including a void; forming a buried dielectric pattern that fills an occupied portion of the deep trench; allowing the second surface of the substrate to undergo an etching process to expose the void; forming a capping pattern that fills the void; and forming an antireflection layer on the second surface of the substrate. The capping pattern may be in contact with the antireflection layer.

### BRIEF DESCRIPTION OF DRAWINGS

FIG. 1 illustrates a simplified block diagram showing an image sensor according to some embodiments.

FIG. 2 illustrates a circuit diagram showing an active pixel sensor array of an image sensor according to some embodiments.

FIG. 3 illustrates a plan view showing an image sensor according to some embodiments.

FIGS. 4A, 4B, and 4E illustrate cross-sectional views taken along lines A-A′, B-B′, and C-C′ of FIG. 3, showing an image sensor according to some embodiments.

FIGS. 4C, 4D, and 4F illustrate enlarged views showing section P of FIGS. 4A, 4B, and 4E, respectively.

FIGS. 5A, 5B, and 5C illustrate cross-sectional views taken along lines A-A′, B-B′, and C-C′ of FIG. 3, showing an image sensor according to some embodiments.

FIGS. 6A to 6J illustrate cross-sectional views taken along lines A-A′, B-B′, and C-C′ of FIG. 3, showing a method of fabricating an image sensor according to some embodiments.

FIG. 7 illustrates a cross-sectional view showing an image sensor according to some embodiments.

FIG. 8 illustrates a cross-sectional view showing an image sensor according to some embodiments.

### DETAILED DESCRIPTION OF EMBODIMENTS

The following will now describe in detail some embodiments with reference to the accompanying drawings.

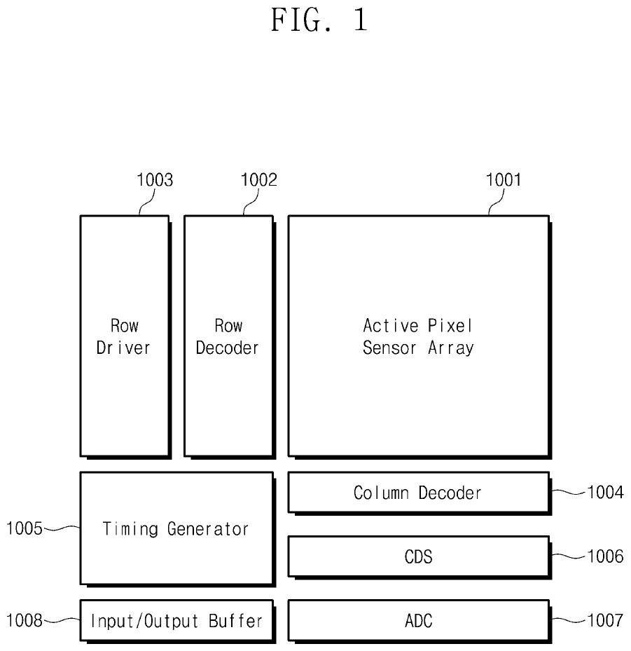

FIG. 1 illustrates a block diagram showing an image sensor according to some embodiments.

Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output (I/O) buffer 1008.

The active pixel sensor array 1001 may include a plurality of two-dimensionally arranged unit pixels, each of which is configured to convert optical signals into electrical signals. The active pixel sensor array 1001 may be driven by a plurality of driving signals such as a pixel selection signal, a reset signal, and a charge transfer signal from the row driver 1003. The correlated double sampler 1006 may be provided with the converted electrical signals.

The row driver 1003 may provide the active pixel sensor array 1001 with several driving signals for driving several unit pixels in accordance with a decoded result obtained from the row decoder 1002. When the unit pixels are arranged in a matrix shape, the driving signals may be provided for respective rows.

The timing generator 1005 may provide timing and control signals to the row decoder 1002 and the column decoder 1004.

The correlated double sampler 1006 may receive the electrical signals generated from the active pixel sensor array 1001, and may hold and sample the received electrical signals. The correlated double sampler 1006 may perform a double sampling operation to sample a specific noise level and a signal level of the electrical signal, and then may output a difference level corresponding to a difference between the noise and signal levels.

The analog-to-digital converter 1007 may convert analog signals, which correspond to the difference level received from the correlated double sampler 1006, into digital signals, and then output the converted digital signals.

The input/output buffer 1008 may latch the digital signals and then sequentially output the latched digital signals to an image signal processing unit (not shown) in response to the decoded result obtained from the column decoder 1004.

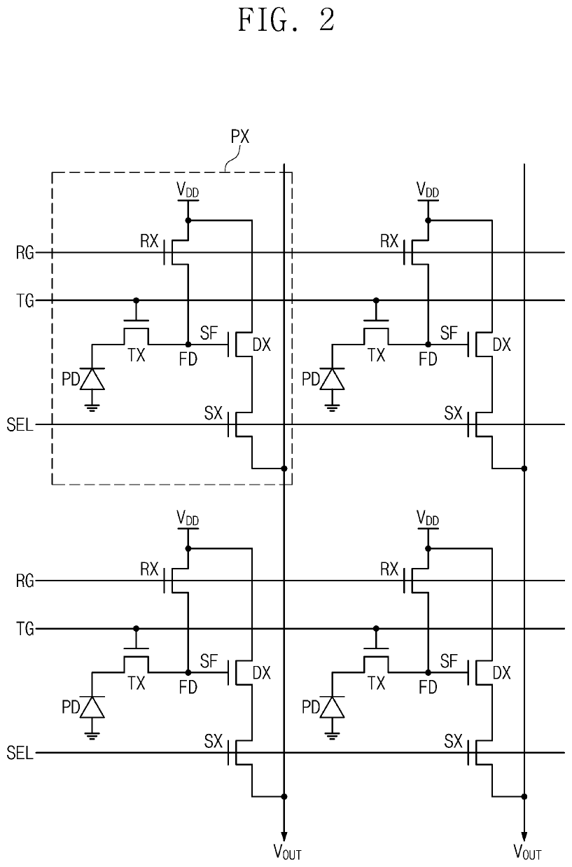

FIG. 2 illustrates a circuit diagram showing an active pixel sensor array of an image sensor according to some embodiments.

Referring to FIGS. 1 and 2, the active pixel sensor array 1001 may include a plurality of unit pixels PX, and the unit pixels PX may be arranged in a matrix shape. Each unit pixel PX may include a transfer transistor TX. Each unit pixel PX may further include logic transistors RX, SX, and DX. The logic transistors RX, SX, and DX may include a reset transistor RX, a selection transistor SX, and a source follower transistor DX. The transfer transistor TX may include a transfer gate TG. Each of the unit pixels PX may further include a photoelectric conversion element PD and a floating diffusion region FD. The logic transistors RX, SX, and DX may be shared by a plurality of unit pixels UP.

The photoelectric conversion element PD may create and accumulate photo-charges in proportion to an amount of externally incident light. The photoelectric conversion element PD may include a photodiode, phototransistor, a photogate, a pinned photodiode, or a combination thereof. The transfer transistor TX may transfer charges generated in the photoelectric conversion element PD into the floating diffusion region FD. The floating diffusion region FD may accumulate and store charges that are generated and transferred from the photoelectric conversion element PD. The source follower transistor DX may be controlled by an amount of photo-charges accumulated in the floating diffusion region FD.

The reset transistor RX may periodically reset the charges accumulated in the floating diffusion region FD. The reset transistor RX may have a drain electrode connected to the floating diffusion region FD and a source electrode connected to a power voltage V_{DD}. When the reset transistor RX is turned on, the floating diffusion region FD may be supplied with the power voltage V_{DD} connected to the source electrode of the reset transistor RX. Accordingly, when the reset transistor RX is turned on, the charges accumulated in the floating diffusion region FD may be exhausted and thus the floating diffusion region FD may be reset.

The source follower transistor DX including a source follower gate SF may serve as a source follower buffer amplifier. The source follower transistor DX may amplify a variation in electrical potential of the floating diffusion region FD and may output the amplified electrical potential to an output line V_{OUT}.

The selection transistor SX including a selection gate SEL may select each row of the unit pixel P to be readout. When the selection transistor SX is turned on, the power voltage V_{DD} may be applied to a drain electrode of the source follower transistor DX.

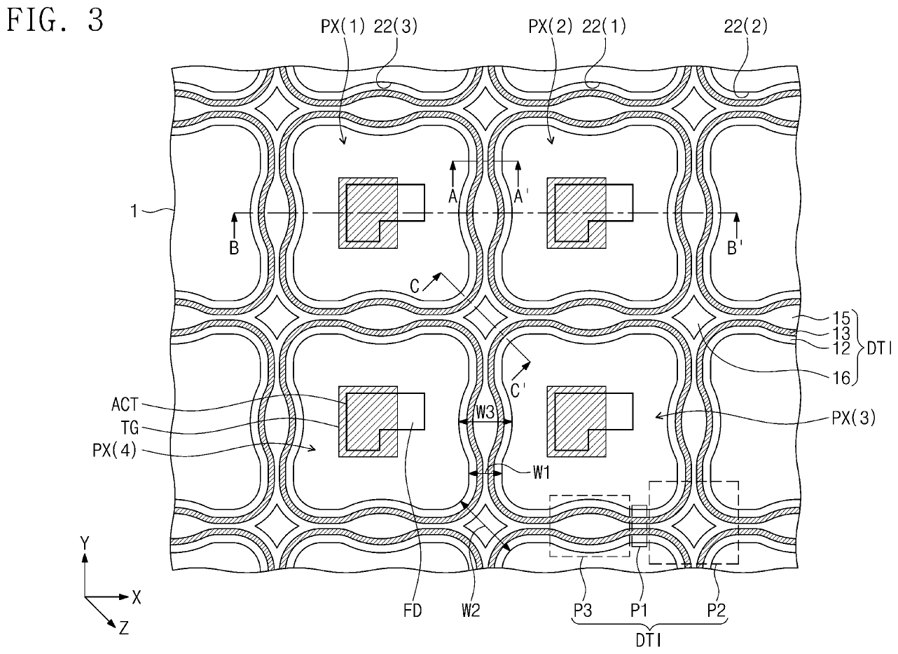

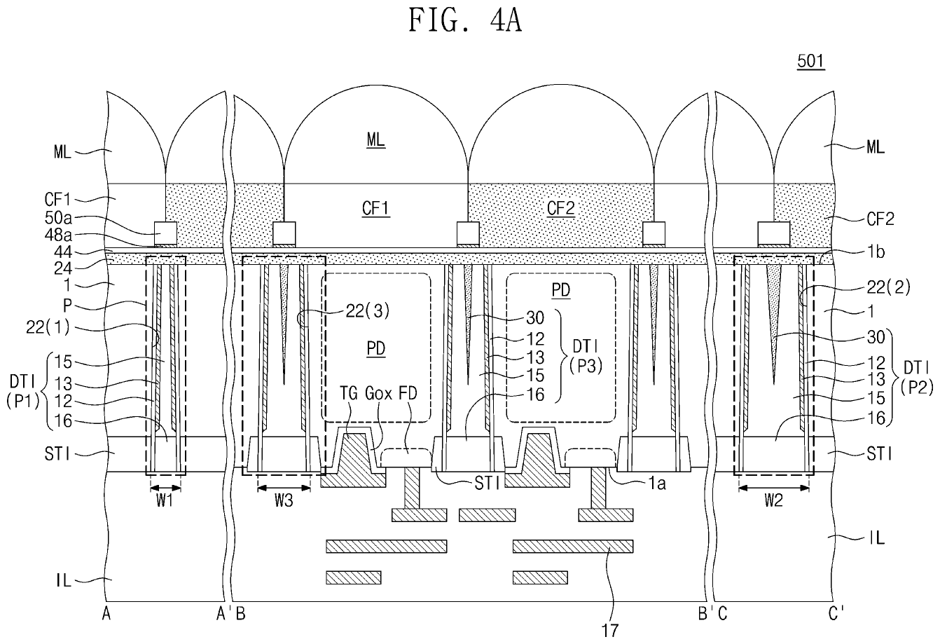

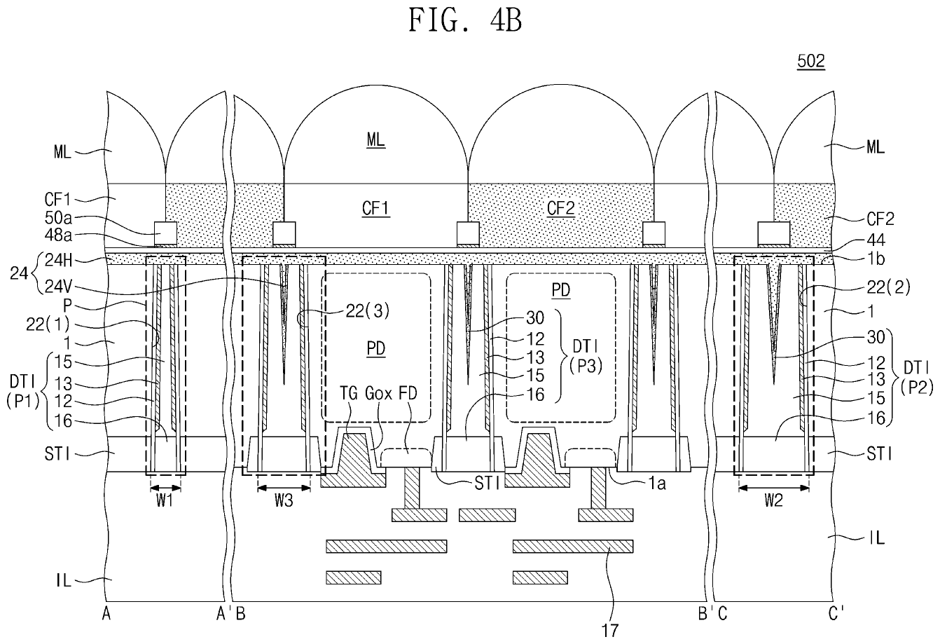

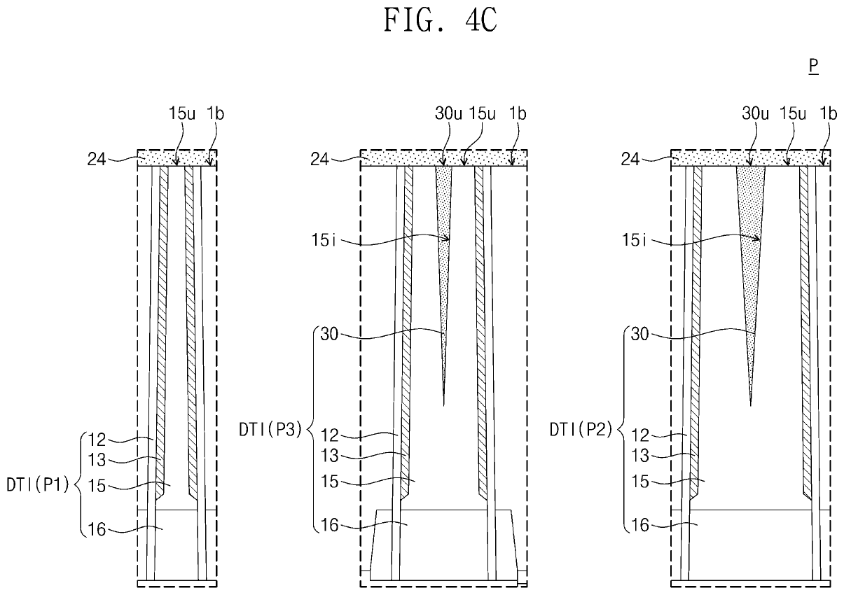

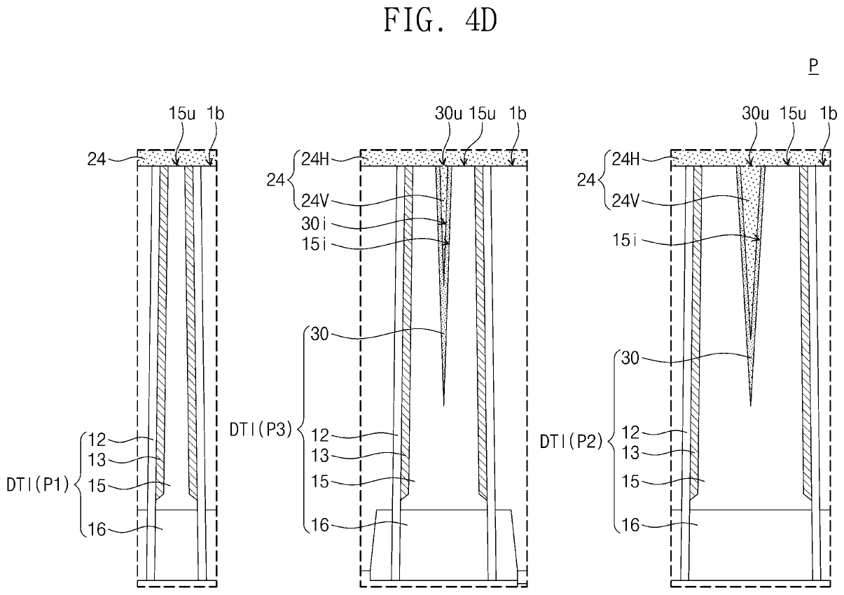

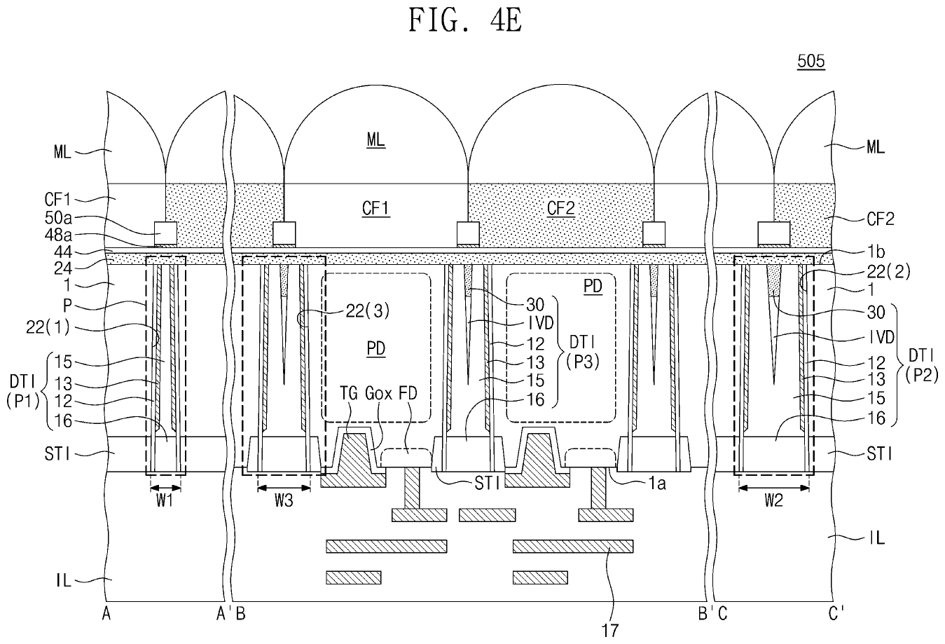

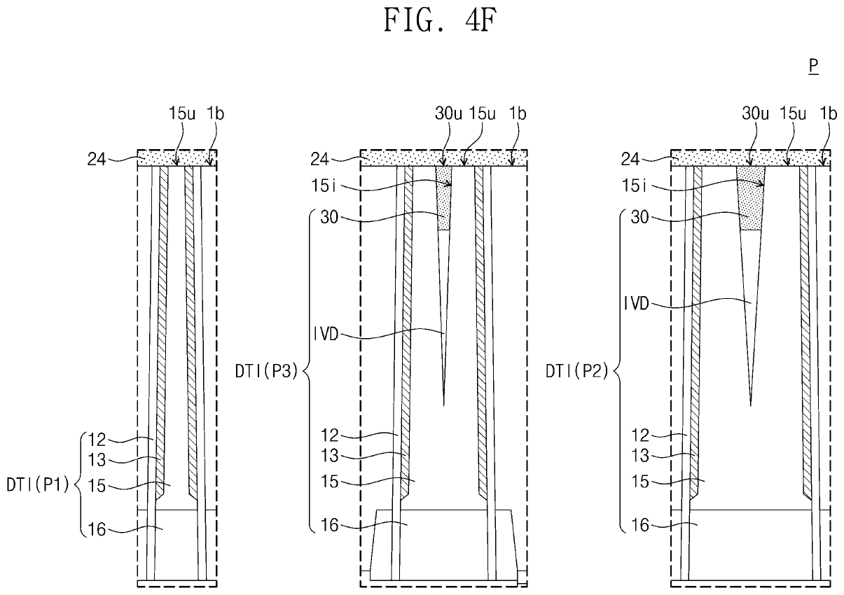

FIG. 3 illustrates a plan view showing an image sensor according to some embodiments. FIG. 4A illustrates a cross-sectional view taken along lines A-A′, B-B′, and C-C′ of FIG. 3, showing an image sensor according to some embodiments. FIG. 4C illustrates an enlarged view showing section P of FIG. 4A.

Referring to FIGS. 3 and 4A, an image sensor 501 according to some embodiments may include a first substrate 1. The first substrate 1 may be, for example, a monocrystalline silicon wafer, a silicon epitaxial layer substrate, or a silicon-on-insulator (SOI) substrate. The first substrate 1 may be doped with impurities having a first conductivity type. For example, the first conductivity type may be a p-type. The first substrate 1 may have a first surface 1a and a second surface 1b that are opposite to each other. In this description, the first surface 1a may be called a front surface 1a, and the second surface 1b may be called a rear surface 1b. The first substrate 1 may include a plurality of unit pixels PX.

The unit pixels PX may include first to fourth pixel pixels PX(1) to PX(4) arranged along a clockwise direction. The first and second pixels PX(1) and PX(2) may be arranged side by side along a first direction X. The fourth and first pixels PX(4) and PX(1) may be arranged side by side along a second direction Y that intersects the first direction X. The first and third pixels PX(1) and PX(3) may be arranged side by side along a third direction Z that intersects both of the first direction X and the second direction Y.

The first substrate 1 may be provided therein with a pixel isolation part DTI that separates and limit the unit pixels PX. The pixel isolation part DTI may have a network shape when viewed in plan.

The pixel isolation part DTI may include first to third isolation parts P1 to P3. The first isolation part P1 may be interposed between the first and second pixels PX(1) and PX(2), and may be adjacent to edges of the first and second pixels PX(1) and PX(2). The second isolation part P2 may be interposed between the first and third pixels PX(1) and PX(3). The third isolation part P3 may be interposed between centers of the first and second pixels PX(1) and PX(2). The first isolation part P1 may have a first width W1 in the first direction X. The second isolation part P2 may have a second width W2 in the third direction Z. The third isolation part P3 may have a third width W3 in the first direction X. The third width W3 may be greater than the first width W1 and less than the second width W2. The pixel isolation part DTI may have an uneven structure on a sidewall thereof.

The pixel isolation part DTI may have therein a deep trench 22 that extends from the first surface 1a toward the second surface 1b of the first substrate 1. The deep trench 22 may include first to third deep trenches 22(1) to 22(3). The first isolation part P1 may be disposed in the first deep trench 22(1). The second isolation part P2 may be disposed in the second deep trench 22(2). The third isolation part P3 may be disposed in the third deep trench 22(3).

An antireflection layer 24 may be disposed on the second surface 1b of the first substrate 1. The antireflection layer 24 may be in contact with the second surface 1b of the first substrate 1. The antireflection layer 24 may be formed of one or single and multiple layers that includes either a metal oxide layer including oxygen whose amount is less than its stoichiometric ratio or a metal fluoride layer including fluorine whose amount is less than its stoichiometric ratio. The antireflection layer 24 may thus have a negative fixed charge. The antireflection layer 24 may be formed of one of metal oxide and metal fluoride each including at least one metal selected from hafnium (Hf), zirconium (Zr), aluminum (Al), tantalum (Ta), titanium (Ti), yttrium (Y), and lanthanides. For example, the antireflection layer 24 may include one or more of a hafnium oxide layer and an aluminum oxide layer.

A first protection layer 44 may be stacked on the antireflection layer 24. The first protection layer 44 may include at least one selected from plasma-enhanced tetraethyl orthosilicate (PETEOS), SiOC, SiO₂, and SiN.

Referring to FIGS. 3, 4A, and 4B, each of the first to third isolation parts P1 to P3 may include a first isolation dielectric pattern 12, a semiconductor pattern 13 and 15, and a buried dielectric pattern 16. The semiconductor pattern 13 and 15 may penetrate the first substrate 1 along a direction perpendicular to the first surface 1a of the first substrate 1.

The first isolation dielectric pattern 12 may be disposed between the first substrate 1 and the semiconductor pattern 13 and 15. The first isolation dielectric pattern 12 may cover an inner sidewall of the deep trench 22. The semiconductor pattern 13 and 15 may cover at least a portion of an inner sidewall of the first isolation dielectric pattern 12. The first isolation dielectric pattern 12 may have at least one single-layered or multi-layered structure of silicon oxide, silicon nitride, and silicon oxynitride.

The semiconductor pattern 13 and 15 may include a first semiconductor pattern 13 and a second semiconductor pattern 15. The first semiconductor pattern 13 may be interposed between the first isolation dielectric pattern 12 and the second semiconductor pattern 15. A top surface 15u of the second semiconductor pattern 15 may be coplanar with the second surface 1b of the first substrate 1.

The semiconductor pattern 13 and 15 may include impurity-doped silicon. The impurity may include, for example, boron. The first semiconductor pattern 13 and the second semiconductor pattern 15 may be in contact with each other. The second semiconductor pattern 15 may connect to each other the first semiconductor patterns 13 that correspondingly surround the unit pixels PX.

The buried dielectric pattern 16 may be positioned on a bottom end of the second semiconductor pattern 15. The buried dielectric pattern 16 may cover a remaining portion of the inner sidewall of the first isolation dielectric pattern 12. The buried dielectric pattern 16 may include a dielectric material whose refractive index is different from that of the first substrate 1. The buried dielectric pattern 16 may include at least one selected from silicon oxide, silicon nitride, and silicon oxynitride.

Each of the second and third isolation parts P2 and P3 may further include a capping pattern 30 in the semiconductor pattern 13 and 15. The capping pattern is configured, in some embodiments to avoid a short circuit between conductive layers due to debris particles (for example, silicon dust) created at a time of a fabrication step of cleaning which applies etching to the image sensor 501. The capping pattern is configured to keep such debris particles away from conductive layers. The capping pattern 30 may extend from the second surface 1b toward the first surface 1a of the first substrate 1. The capping pattern 30 may have a width in a direction parallel to the second surface 1b of the first substrate 1. The width of the capping pattern 30 may decrease in a direction from the second surface 1b toward the first surface 1a of the first substrate 1. For example, a width of the capping pattern may decrease when viewed beginning at the second surface and moving toward the first surface of the substrate.

The capping pattern 30 may be disposed on an inner surface 15i of the second semiconductor pattern 15. The capping pattern 30 may fill a space surrounded by the inner surface 15i of the second semiconductor pattern 15. In the second semiconductor pattern 15, the capping pattern 30 may extend along a direction perpendicular to the second surface 1b of the first substrate 1 to penetrate a portion of the second semiconductor pattern 15. The capping pattern 30 may be spaced apart from the first semiconductor pattern 13 across the second semiconductor pattern 15.

A top surface 30u of the capping pattern 30 may be coplanar with a top surface 15u of the second semiconductor pattern 15 and the second surface 1b of the first substrate 1. The capping pattern 30 may be in contact with the antireflection layer 24. The capping pattern 30 may fill a space between the antireflection layer 24 and the second semiconductor pattern 15. The capping pattern 30 may include at least one selected from silicon oxide, silicon, metal, and high-k dielectrics. For example, the capping pattern 30 may include at least one selected from polysilicon, amorphous polysilicon, crystalline silicon, silicon carbide (SiC), silicon-germanium (SiGe), silicon oxide (SiO₂), and silicon carbonitride (SiCN). For another example, the capping pattern 30 may include at least one selected from copper (Cu), tungsten (W), and aluminum (Al). For another example, the capping pattern 30 may include at least one selected from aluminum oxide (Al₂O₃), hafnium oxide (HfO), and titanium oxide (TiO₂). Preferably, the capping pattern 30 may include at least one selected from silicon oxide, polysilicon, and amorphous polysilicon.

Referring back to FIGS. 3 and 4A, the first substrate 1 may include photoelectric conversion elements PD in corresponding unit pixels PX. The photoelectric conversion elements PD may be doped with impurities having a second conductivity type opposite to the first conductivity type. The second conductivity type may be, for example, an n-type. The n-type impurities doped in the photoelectric conversion element PD and the p-type impurities doped in the first substrate 1 therearound may constitute a PN junction to provide a photodiode.

The first substrate 1 may include therein device isolation parts STI adjacent to the first surface 1a. The device isolation parts STI may have a single-layered or multi-layered structure of at least one selected from silicon oxide, silicon nitride, and silicon oxynitride. The pixel isolation part DTI may penetrate the device isolation parts STI. In each unit pixel PX, the device isolation parts STI may limit active sections ACT adjacent to the first surface 1a. The active sections ACT may be provided for the transistors TX, RX, DX, and SX of FIG. 2.

On each pixel PX, a transfer gate TG may be disposed on the first surface 1a of the first substrate 1. A portion of the transfer gate TG may extend into the first substrate 1. The transfer gate TG may have a vertical type. Alternatively, the transfer gate TG may be a planar type that does not extend into the first substrate 1. A gate dielectric layer Gox may be interposed between the transfer gate TG and the first substrate 1. A floating diffusion region FD may be disposed in the first substrate 1 on one side of the transfer gate TG. The floating diffusion region FD may be doped with impurities having, for example, the second conductivity type.

The image sensor 501 may be a backside illumination image sensor. The first substrate 1 may receive light through the second surface 1b thereof. Electron-hole pairs may be created from the incident light at the PN junction. These created electrons may move toward the photoelectric conversion element PD. When a voltage is applied to the transfer gate TG, the electrons may move toward the floating diffusion region FD.

The first surface 1a may be covered with a first interlayer dielectric layer IL. The first interlayer dielectric layer IL may be formed of a multiple layer including at least one selected from a silicon oxide layer, a silicon nitride layer, a silicon oxynitride layer, and a porous low-k dielectric layer. The first interlayer dielectric layer IL may have first wiring lines 17 disposed therein. The floating diffusion region FD may be connected to the first wiring lines 17.

The first protection layer 44 may be provided thereon with light-shield patterns 48a. Low-refractive patterns 50a may be correspondingly disposed on the light-shield patterns 48a. The light-shield pattern 48a and the low-refractive pattern 50a may overlap the pixel isolation part DTI and may have a grid shape. The light-shield pattern 48a may include, for example, titanium. The low-refractive patterns 50a may have the same thickness and may include the same organic material. The low-refractive pattern 50a may have a refractive index less than those of color filters CF1 and CF2. For example, the low-refractive pattern 50a may have a refractive index equal to or less than about 1.3. The light-shield pattern 48a and the low-refractive pattern 50a may prevent crosstalk between neighboring unit pixels UP.

The color filters CF1 and CF2 may be disposed between the low-refractive patterns 50a. Each of the color filters CF1 and CF2 may have one of blue, green, and red colors. Alternatively, the color filters CF1 and CF2 may include different colors such as cyan, magenta, or yellow.

In the image sensor 501 according to the present embodiment, the color filters CF1 and CF2 may be arranged in Bayer pattern. Alternatively, the color filters CF1 and CF2 may be arranged in one of 2×2 Tetra, 3×3 Nona, and 4×4 Hexadeca patterns.

Microlenses ML may be disposed on the color filters CF1 and CF2. The microlenses ML may have their edges that are in contact with and connected to each other.

The image sensor 501 according to some embodiments may include a capping pattern 30 in the pixel isolation part DTI. The capping pattern 30 may fill voids in the semiconductor pattern 13 and 15 to protect the semiconductor pattern 13 and 15. Therefore, the image sensor 501 may improve in reliability.

FIG. 4B illustrates a cross-sectional view taken along lines A-A′, B-B′, and C-C′ of FIG. 3, showing an image sensor according to some embodiments. FIG. 4D illustrates an enlarged view showing section P depicted in FIG. 4B. A description repetitive to that of the image sensor discussed with reference to FIGS. 3, 4A, and 4C will be omitted for brevity of description.

Referring to FIGS. 3, 4B, and 4D, an image sensor 502 according to some embodiments may include a capping pattern 30. The capping pattern 30 may conformally cover the inner surface 15i of the second semiconductor pattern 15. The capping pattern 30 may have a film shape that covers the inner surface 15i of the second semiconductor pattern 15. The capping pattern 30 may have a constant thickness on the inner surface 15i of the second semiconductor pattern 15.

The antireflection layer 24 may include a horizontal part 24H and a vertical part 24V. The horizontal part 24H of the antireflection layer 24 may extend along a direction parallel to and on the second surface 1b of the first substrate 1. The vertical part 24V of the antireflection layer 24 may extend into the first substrate 1. The vertical part 24V of the antireflection layer 24 may extend along a direction perpendicular to and on the second surface 1b of the first substrate 1, thereby covering an inner surface 30i of the capping pattern 30. The vertical part 24V of the antireflection layer 24 may fill a space between the inner surface 30i of the capping pattern 30 and the horizontal part 24H of the antireflection layer 24.

FIG. 4E illustrates a cross-sectional view taken along lines A-A′, B-B′, and C-C′ of FIG. 3, showing an image sensor according to some embodiments. FIG. 4F illustrates an enlarged view showing section P depicted in FIG. 4E. A description repetitive to that of the image sensor discussed with reference to FIGS. 3, 4A, 4B, 4C, and 4D will be omitted for brevity of description.

Referring to FIGS. 3, 4E, and 4F, an image sensor 505 according to some embodiments may include a capping pattern 30 and an inner void IVD below the capping pattern 30. The capping pattern 30 may be disposed on an upper portion of the inner surface 15i of the second semiconductor pattern 15. The inner void IVD may be disposed on a lower portion of the inner surface 15i of the second semiconductor pattern 15. For example, the inner void IVD may be surrounded by the second semiconductor pattern 15 and the capping pattern 30. The inner void IVD may have a width in a direction parallel to the second surface 1b of the first substrate 1, and the width may decrease with decreasing distance from the first surface 1a of the first substrate 1.

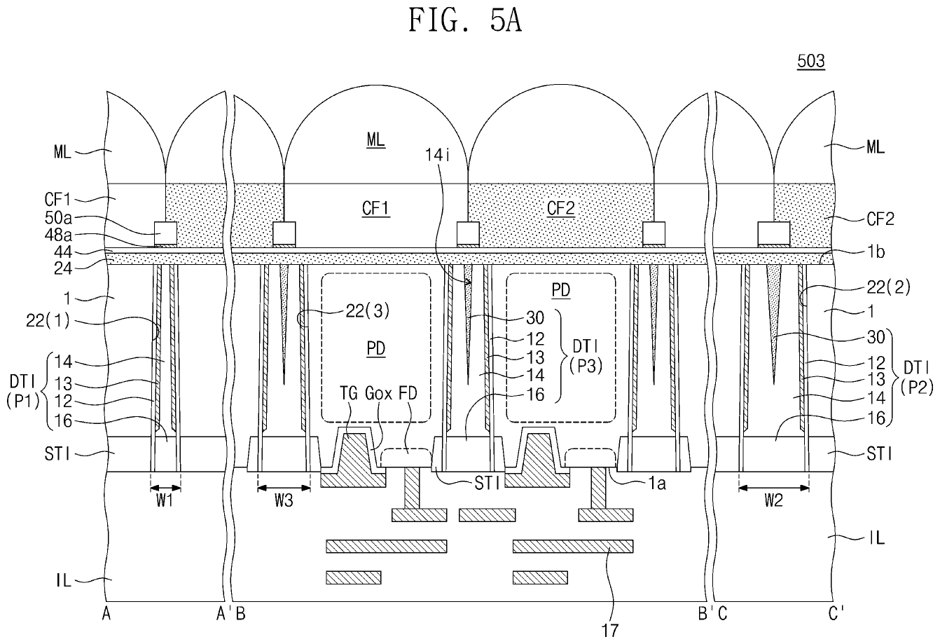

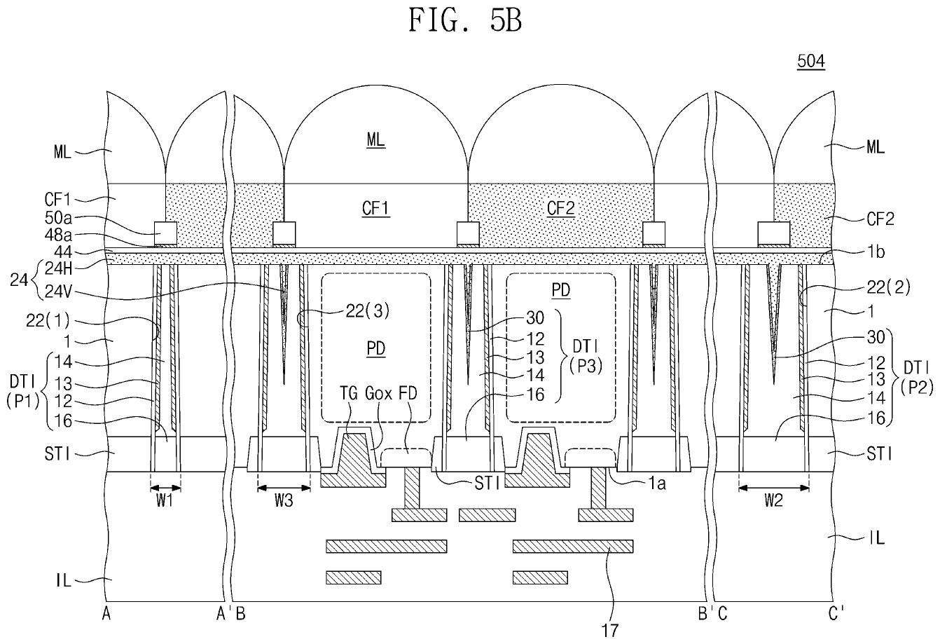

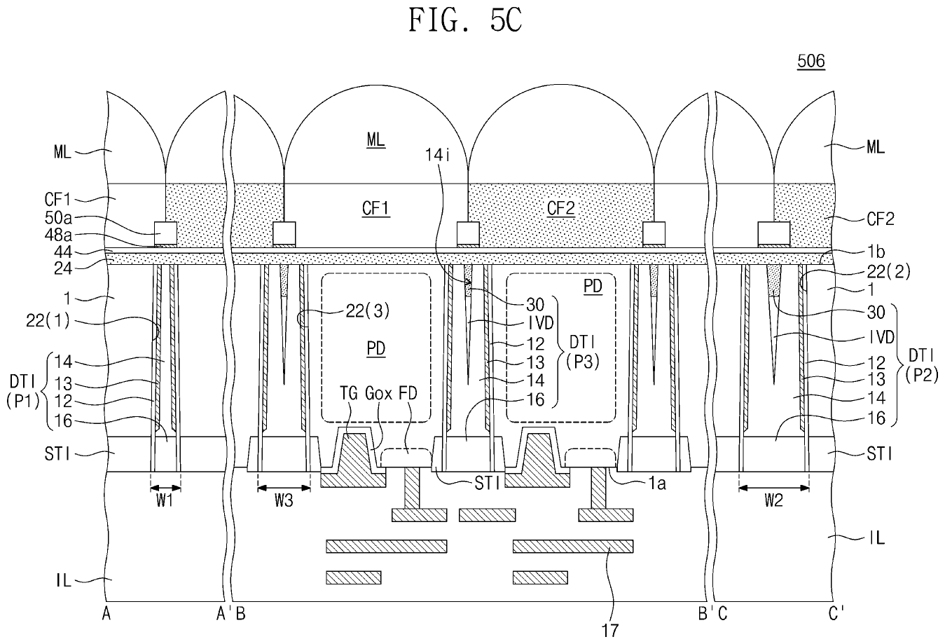

FIG. 5A illustrates a cross-sectional view taken along lines A-A′, B-B′, and C-C′ of FIG. 3, showing an image sensor according to some embodiments. A description repetitive to that of the image sensor discussed with reference to FIGS. 3, 4A, and 4C will be omitted for brevity of description.

Referring to FIG. 5A, in an image sensor 503 according to some embodiments, each of the first and third isolation parts P1 and P3 of the pixel isolation part DTI may include a first isolation dielectric pattern 12, a dielectric pattern 14 and 16, and a first semiconductor pattern 13. The dielectric pattern 14 and 16 may penetrate the first substrate 1 along a direction perpendicular to the first surface 1a of the first substrate 1. The first isolation dielectric pattern 12 may be disposed between the first substrate 1 and the dielectric pattern 14 and 16. The dielectric pattern 14 and 16 may cover at least a portion of an inner wall of the first isolation dielectric pattern 12.

The dielectric pattern 14 and 16 may include a buried dielectric pattern 16 adjacent to the first surface 1a of the first substrate 1 and a first dielectric pattern 14 adjacent to the second surface 1b of the first substrate 1. The first semiconductor pattern 13 may be disposed between the first isolation dielectric pattern 12 and the first dielectric pattern 14. A top surface of the first dielectric pattern 14 may be coplanar with the second surface 1b of the first substrate 1. The first dielectric pattern 14 may include at least one selected from silicon oxide, silicon nitride, and silicon oxynitride.

The third isolation part P3 may further include a capping pattern 30 in the first dielectric pattern 14. The capping pattern 30 may extend from the second surface 1b toward the first surface 1a of the first substrate 1. The capping pattern 30 may have a width in a direction parallel to the second surface 1b of the first substrate 1. The width of the capping pattern 30 may decrease in a direction from the second surface 1b toward the first surface 1a of the first substrate 1.

The capping pattern 30 may be disposed on an inner surface 14i of the first dielectric pattern 14. The capping pattern 30 may fill a space surrounded by the inner surface 14i of the first dielectric pattern 14. The capping pattern 30 may be spaced apart from the first semiconductor pattern 13 across the first dielectric pattern 14. The capping pattern 30 may be interposed between the antireflection layer 24 and the first dielectric pattern 14. The capping pattern 30 may be in contact with the antireflection layer 24. The capping pattern 30 may fill a space between the antireflection layer 24 and the first dielectric pattern 14.

FIG. 5B illustrates a cross-sectional view taken along lines A-A′, B-B′, and C-C′ of FIG. 3, showing an image sensor according to some embodiments. A description repetitive to that of the image sensor discussed with reference to FIGS. 3, 4A, and 4C will be omitted for brevity of description.

Referring to FIG. 5B, in an image sensor 504 according to some embodiments, each of the first and third isolation parts P1 and P3 of the pixel isolation part DTI may include a first isolation dielectric pattern 12, a dielectric pattern 14 and 16, and a first semiconductor pattern 13. The dielectric pattern 14 and 16 may penetrate the first substrate 1 along a direction perpendicular to the first surface 1a of the first substrate 1. The first isolation dielectric pattern 12 may be disposed between the first substrate 1 and the dielectric pattern 14 and 16. The dielectric pattern 14 and 16 may cover at least a portion of an inner wall of the first isolation dielectric pattern 12.

The dielectric pattern 14 and 16 may include a buried dielectric pattern 16 adjacent to the first surface 1a of the first substrate 1 and a first dielectric pattern 14 adjacent to the second surface 1b of the first substrate 1. The first semiconductor pattern 13 may be disposed between the first isolation dielectric pattern 12 and the first dielectric pattern 14. A top surface of the first dielectric pattern 14 may be coplanar with the second surface 1b of the first substrate 1. The first dielectric pattern 14 may include at least one selected from silicon oxide, silicon nitride, and silicon oxynitride.

The third isolation part P3 may further include a capping pattern 30 in the first dielectric pattern 14. The capping pattern 30 may extend from the second surface 1b toward the first surface 1a of the first substrate 1. The capping pattern 30 may have a width in a direction parallel to the second surface 1b of the first substrate 1. The width of the capping pattern 30 may decrease in a direction from the second surface 1b toward the first surface 1a of the first substrate 1.

The capping pattern 30 may be disposed on an inner surface 14i of the first dielectric pattern 14. The capping pattern 30 may conformally cover the inner surface 14i of the first dielectric pattern 14. The capping pattern 30 may have a film shape that covers the inner surface 14i of the first dielectric pattern 14. The capping pattern 30 may have a constant thickness on the inner surface 14i of the first dielectric pattern 14. The capping pattern 30 may be spaced apart from the first semiconductor pattern 13 across the first dielectric pattern 14. The capping pattern 30 may be interposed between the antireflection layer 24 and the first dielectric pattern 14. The capping pattern 30 may be in contact with the antireflection layer 24. The capping pattern 30 may fill a space between the antireflection layer 24 and the first dielectric pattern 14.

The antireflection layer 24 may include a horizontal part 24H and a vertical part 24V. The horizontal part 24H of the antireflection layer 24 may extend along a direction parallel to and on the second surface 1b of the first substrate 1. The vertical part 24V of the antireflection layer 24 may extend into the first substrate 1. The vertical part 24V of the antireflection layer 24 may extend along a direction perpendicular to and on the second surface 1b of the first substrate 1, thereby covering an inner surface of the capping pattern 30. The vertical part 24V of the antireflection layer 24 may fill a space between the inner surface of the capping pattern 30 and the horizontal part 24H of the antireflection layer 24.

FIG. 5C illustrates a cross-sectional view taken along lines A-A′, B-B′, and C-C′ of FIG. 3, showing an image sensor according to some embodiments. A description repetitive to that of the image sensor discussed with reference to FIGS. 3, 4A, 4C, and 4E will be omitted for brevity of description.

Referring to FIG. 5C, in an image sensor 506 according to some embodiments, each of the first and third isolation parts P1 and P3 of the pixel isolation part DTI may include a first isolation dielectric pattern 12, a dielectric pattern 14 and 16, and a first semiconductor pattern 13. The dielectric pattern 14 and 16 may penetrate the first substrate 1 along a direction perpendicular to the first surface 1a of the first substrate 1. The first isolation dielectric pattern 12 may be disposed between the first substrate 1 and the dielectric pattern 14 and 16. The dielectric pattern 14 and 16 may cover at least a portion of an inner wall of the first isolation dielectric pattern 12.

The dielectric pattern 14 and 16 may include a buried dielectric pattern 16 adjacent to the first surface 1a of the first substrate 1 and a first dielectric pattern 14 adjacent to the second surface 1b of the first substrate 1. The first semiconductor pattern 13 may be disposed between the first isolation dielectric pattern 12 and the first dielectric pattern 14. A top surface of the first dielectric pattern 14 may be coplanar with the second surface 1b of the first substrate 1. The first dielectric pattern 14 may include at least one selected from silicon oxide, silicon nitride, and silicon oxynitride.

The isolation part P3 may include a capping pattern 30 in the first dielectric pattern 14 and an inner void IVD below the capping pattern 30. The capping pattern 30 may be disposed on an upper portion of an inner surface 14i of the first dielectric pattern 14. The inner void IVD may be disposed on a lower portion of the inner surface 14i of the first dielectric pattern 14. For example, the inner void IVD may be surrounded by the first dielectric pattern 14 and the capping pattern 30. The inner void IVD may have a width in a direction parallel to the second surface 1b of the first substrate 1, and the width may decrease with decreasing distance from the first surface 1a of the first substrate 1.

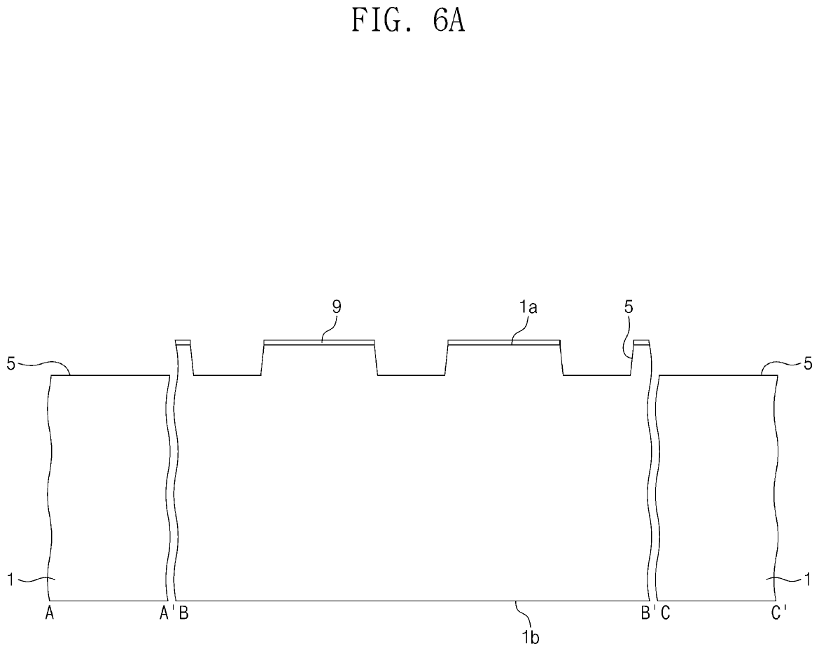

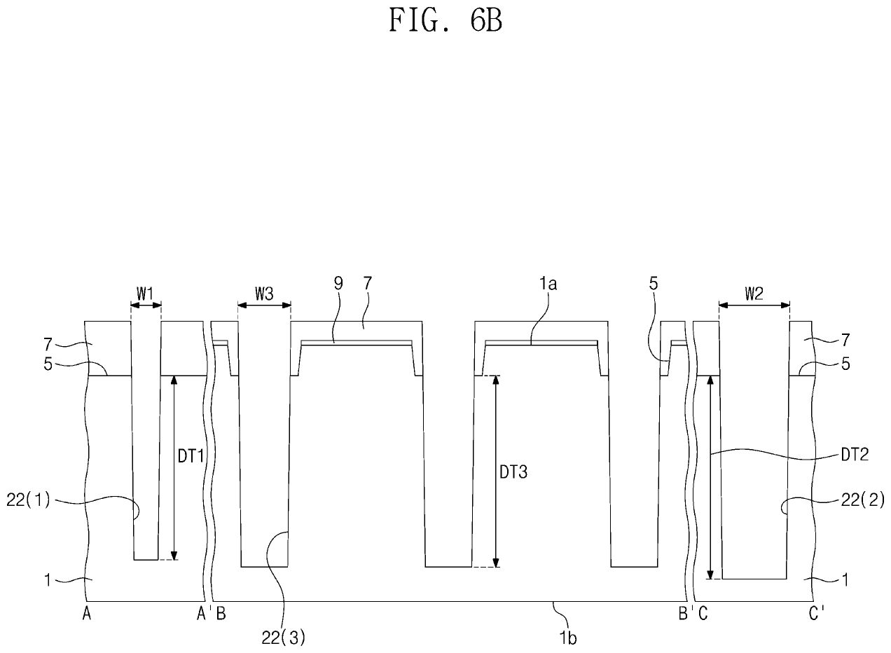

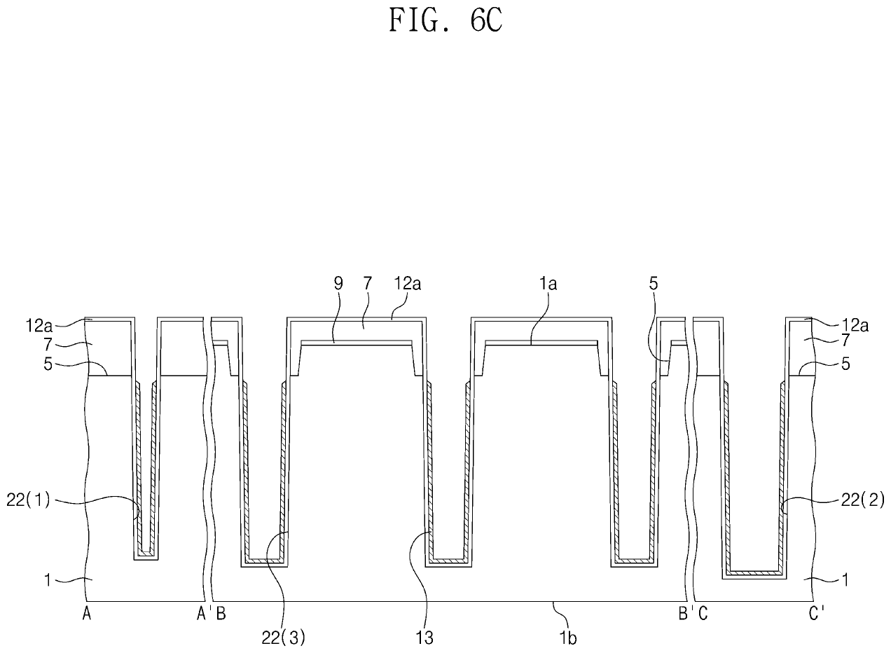

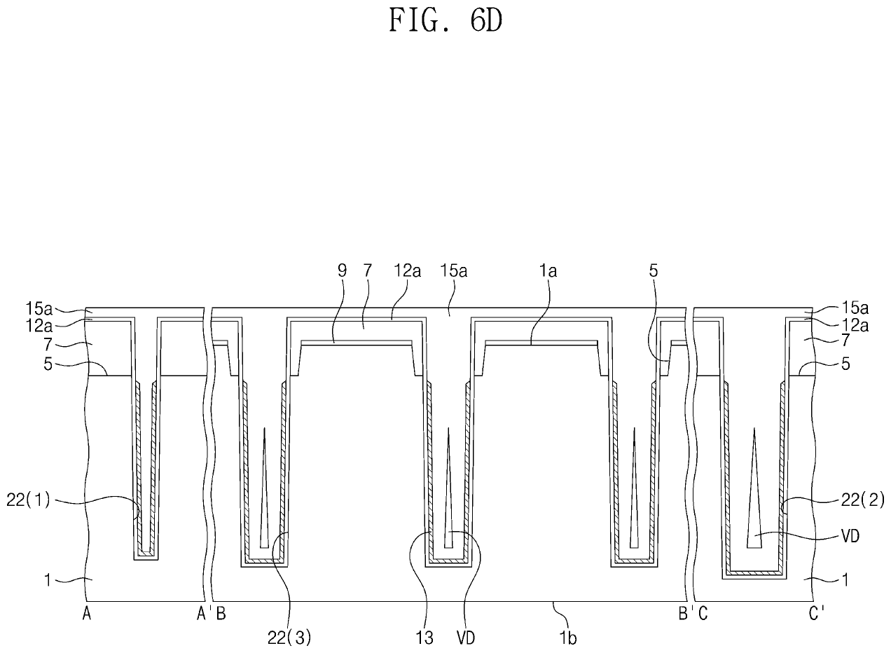

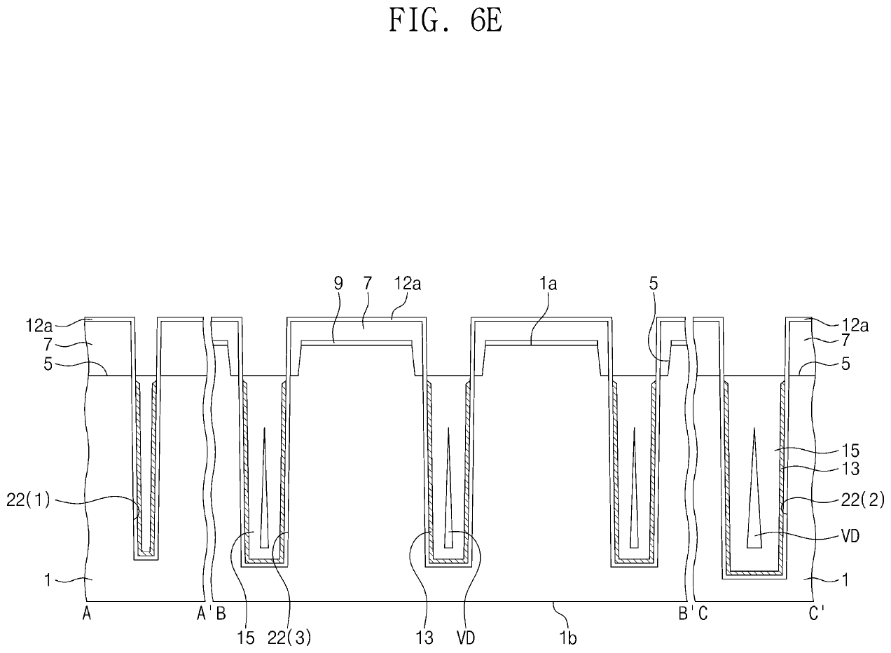

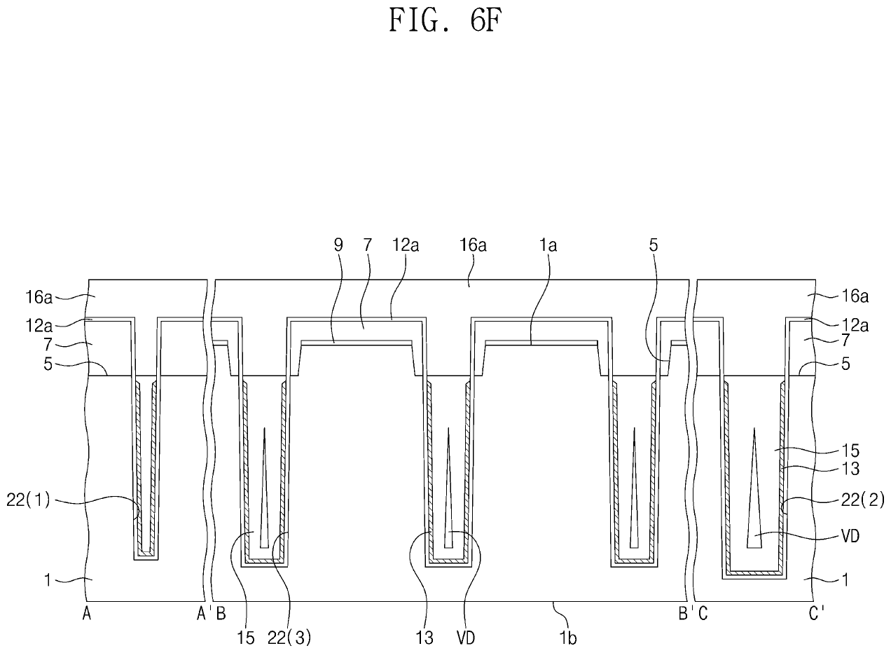

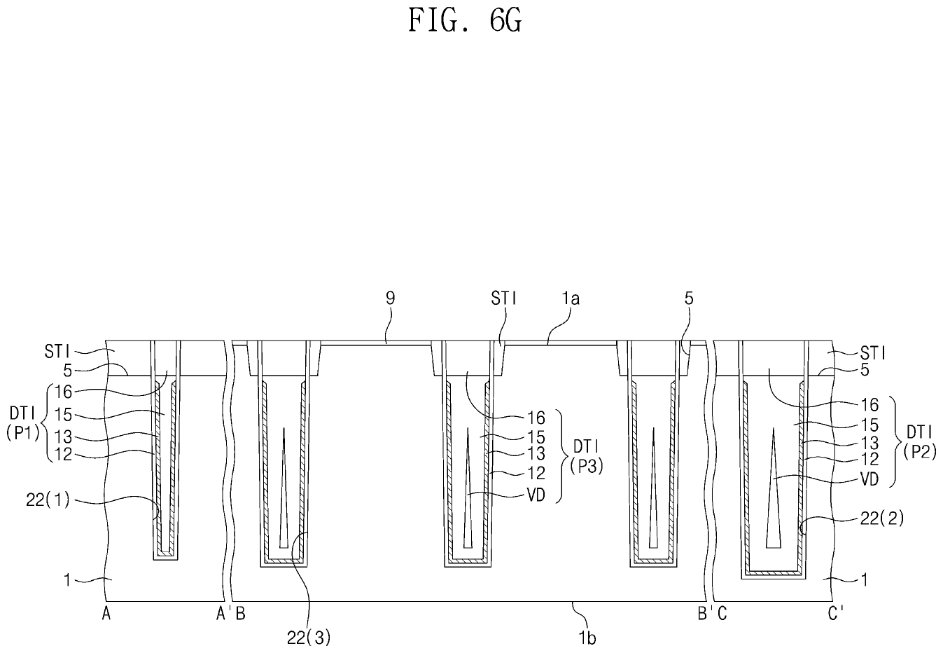

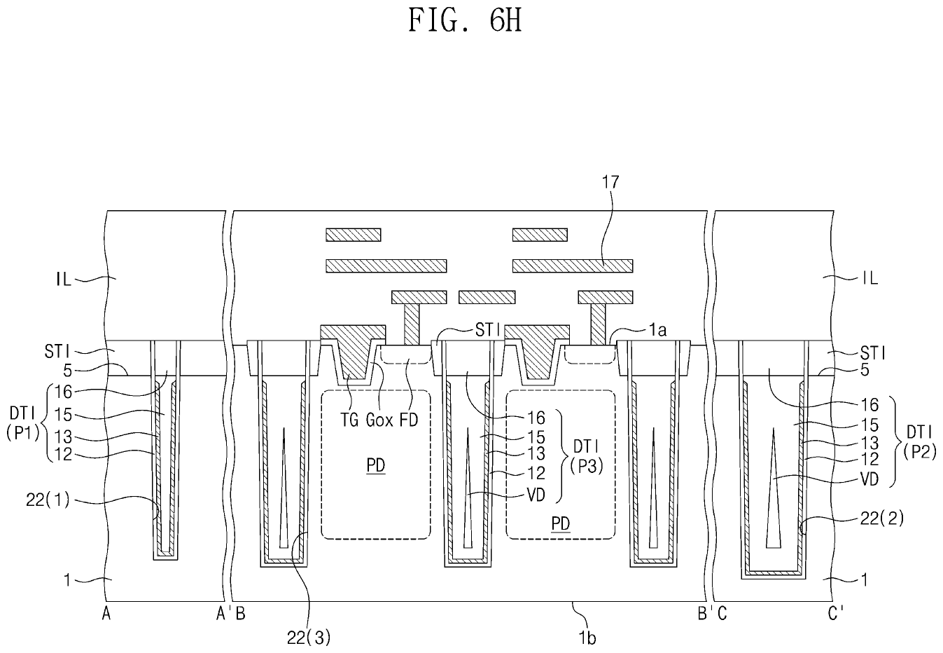

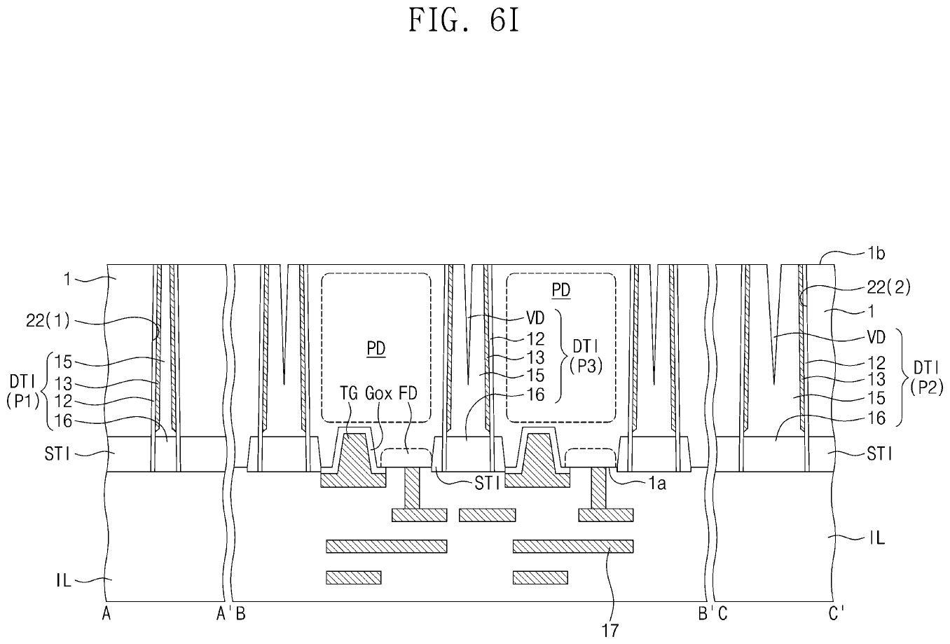

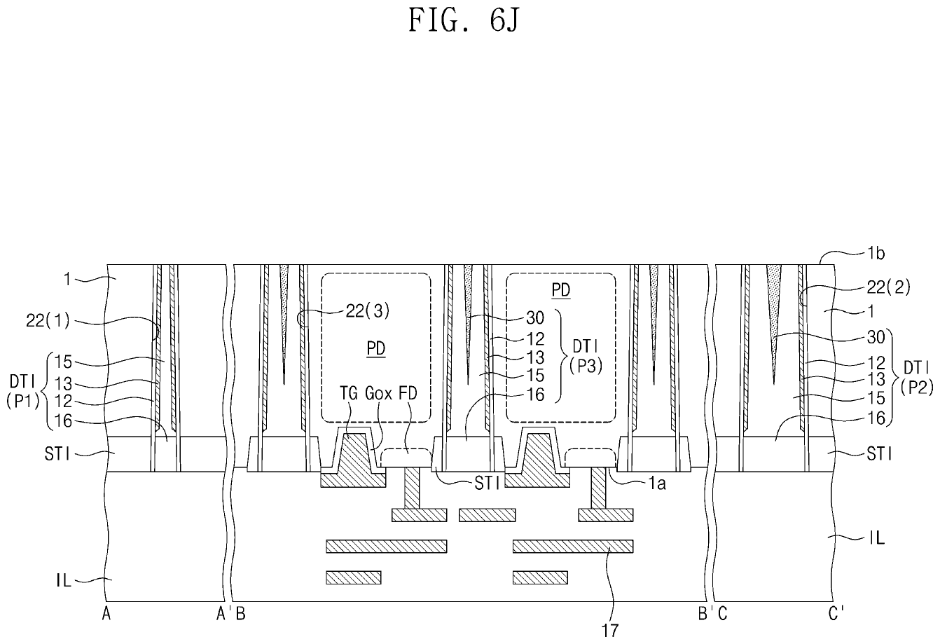

FIGS. 6A to 6J illustrate cross-sectional views taken along lines A-A′, B-B′, and C-C′ of FIG. 3, showing a method of fabricating an image sensor according to some embodiments. A description repetitive to that of the image sensor discussed with reference to FIGS. 3, 4A, and 4C will be omitted for brevity of description.

Referring to FIG. 6A, a first substrate 1 may be prepared. A first mask pattern 9 may be formed on a first surface 1a of the first substrate 1. The first mask pattern 9 may have a single-layered or multi-layered structure formed of at least one selected from, for example, silicon oxide, silicon nitride, and silicon oxynitride. The first mask pattern 9 may limit positions of active sections ACT on the first surface 1a, as shown in FIG. 3. The first mask pattern 9 may be used as an etching mask to etch the first surface 1a of the first substrate 1 to form a shallow trench 5.

Referring to FIG. 6B, a second mask pattern 7 may be formed on the first surface 1a of the first substrate 1. The second mask pattern 7 may fill a portion of the shallow trench 5, while covering the first mask pattern 9. The second mask pattern 7 may limit a position of a pixel isolation part (see DTI of FIG. 3). The second mask pattern 7 may partially expose a bottom surface of the shallow trench 5. The second mask pattern 7 may have a single-layered or multi-layered structure including at least one selected from silicon oxide, SiN, SiCN, and SiOCN.

The second mask pattern 7 may be used as an etching mask to etch the first substrate 1 to form a deep trench 22. The deep trench 22 may extend into the first substrate 1 from the first surface 1a of the first substrate 1. When the deep trench 22 is formed, interference between etchants may form the deep trench 22 to have a shape the same as or similar to that of the pixel isolation part DTI depicted in FIG. 3. For example, the deep trench 22 may be formed to include first to third deep trenches 22(1) to 22(3). The first deep trench 22(1) may be positioned between first and second pixels (see PX(1) and PX(2) of FIG. 3), and may be adjacent to edges of the first and second pixels PX(1) and PX(2). The second deep trench 22(2) may be positioned between first and third pixels (see PX(1) and PX(3) of FIG. 3). The third deep trench 22(3) may be interposed between centers of the first and second pixels PX(1) and PX(2). The first deep trench 22(1) may be formed to have a first width W1 in a first direction (see X of FIG. 3) and a first depth DT1 from the bottom surface of the shallow trench 5. The second deep trench 22(2) may be formed to have a second width W2 in a third direction (see Z of FIG. 3) and a second depth DT2 from the bottom surface of the shallow trench 5. The third deep trench 22(3) may be formed to have a third width W3 in the first direction X and a third depth DT3 from the bottom surface of the shallow trench 5. The third width W3 may be greater than the first width W1 and less than the second width W2. The third depth DT3 may be greater than the first depth DT1 and less than the second depth DT2.

Referring to FIG. 6C, a first isolation dielectric layer 12a may be formed on the first surface 1a of the first substrate 1 in which the deep trench 22 is formed, thereby covering an inner wall of the deep trench 22. Atomic layer deposition (ALD) may be employed to conformally form the first isolation dielectric layer 12a. The first isolation dielectric layer 12a may have a constant thickness irrespective of position. The first isolation dielectric layer 12a may be formed to have a single-layered or multi-layered structure including at least one selected from silicon oxide, silicon nitride, silicon oxynitride, and silicon carbonitride.

A first semiconductor pattern 13 may be formed in the deep trench 22 to cover the first isolation dielectric layer 12a. The first semiconductor pattern 13 may be formed by conformally forming a first semiconductor layer (not shown) on the first isolation dielectric layer 12a and performing an etch-back process on the first semiconductor layer. When the first semiconductor layer is formed, first impurities may be doped into the first semiconductor layer. A top end of the first semiconductor pattern 13 may be formed lower than the bottom surface of the shallow trench 5.

Referring to FIG. 6D, a second semiconductor layer 15a may be formed on the first surface 1a of the first substrate 1. The second semiconductor layer 15a may be formed on the first surface 1a of the first substrate 1, thereby filling the deep trench 22. The second semiconductor layer 15a may include a void VD in the deep trench 22.

Referring to FIG. 6E, the second semiconductor layer 15a may be etched-back to form a second semiconductor pattern 15. A top end of the second semiconductor pattern 15 may be located at the same height as that of the bottom surface of the shallow trench 5. The second semiconductor pattern 15 may fill a portion of the deep trench 22.

Referring to FIG. 6F, a buried dielectric layer 16a may be formed on the first surface 1a of the first substrate 1, thereby filling an upper portion of the deep trench 22. The buried dielectric layer 16a may include at least one selected from silicon oxide, silicon nitride, silicon oxynitride, and silicon carbonitride. An annealing process may be additionally performed to crystallize the semiconductor pattern 13 and 15. In this step, the first impurities (e.g., boron) doped in the first semiconductor pattern 13 may diffuse into the second semiconductor pattern 15.

Referring to FIG. 6G, a planarization process may be performed to partially remove the second mask pattern 7 on the first mask pattern 9, the first isolation dielectric layer 12a, and the buried dielectric layer 16a, and to form a pixel isolation part DTI in the deep trench 22. This process may form a buried dielectric pattern 16 that fills an unoccupied portion of the deep trench 22. In the process (e.g., chemical mechanical polishing (CMP)), the first mask pattern 9 may serve as a polish stop layer. A portion of the second mask pattern 7 may remain to be a device isolation part STI.

Referring to FIG. 6H, the first mask pattern 9 may be removed to expose the first surface 1a of the first substrate 1. Therefore, top ends of the pixel isolation part DTI and the device isolation part STI may upwardly protrude from the first surface 1a of the first substrate 1. The first substrate 1 may undergo an ion implantation process to form a photoelectric conversion element PD. A transfer gate TG, a gate dielectric layer Gox, and a floating diffusion region FD may be formed on the first surface 1a of the first substrate 1. A first interlayer dielectric layer IL and first wiring lines 17 may be formed on the first surface 1a of the first substrate 1.

Referring to FIG. 6I, a second surface 1b of the first substrate 1 may undergo an etching process to partially remove the first substrate 1 and the pixel isolation part DTI. The etching process may expose the void VD, the first isolation dielectric pattern 12, and the first and second semiconductor patterns 13 and 15 of the pixel isolation part DTI. For example, the etching process may include a chemical mechanical polishing (CMP) process.

Referring to FIG. 6J, a capping pattern 30 may be formed to fill the exposed void VD. The formation of the capping pattern 30 may include depositing a capping layer (not shown) on the second surface 1b of the first substrate 1, and performing an etching process on the capping layer. The etching process may include etching the capping layer until a top surface of the second semiconductor pattern 15 is exposed. The capping layer may include at least one selected from polysilicon and amorphous polysilicon.

Referring back to FIG. 4A, an antireflection layer 24 may be formed on the second surface 1b of the first substrate 1. Afterwards, typical processes may be performed to form a first protection layer 44, a light-shield pattern 48a, a low-refractive pattern 50a, color filters CF1 and CF2, and microlenses ML on the second surface 1b of the first substrate 1. An image sensor 501 may thus be fabricated.

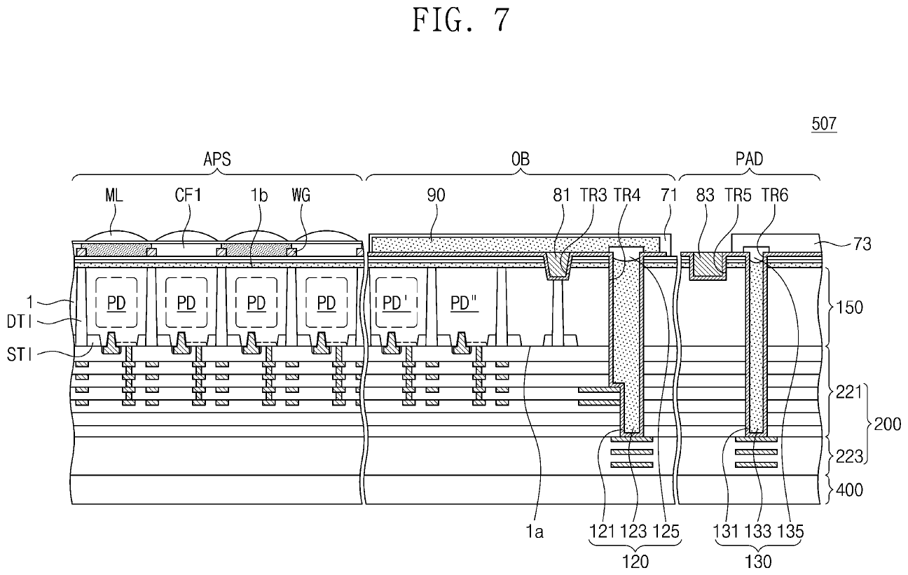

FIG. 7 illustrates a cross-sectional view showing an image sensor according to some embodiments.

Referring to FIG. 7, an image sensor 507 according to the present embodiment may include a first substrate 1 including a pixel array area APS, an optical black area OB, and a pad area PAD, and may also include a wiring layer 200 on a front surface 1a of the first substrate 1 and a second substrate 400 on the wiring layer 200. The wiring layer 200 may include an upper wiring layer 221 and a lower wiring layer 223. The pixel array area APS may include a plurality of unit pixels PX. The pixel array area APS may be provided thereon with a pixel isolation part DTI that separates/limits the plurality of unit pixels PX. The pixel isolation part DTI disposed on the pixel array area APS may be substantially the same as that discussed above with reference to FIGS. 3 to 5B.

On the optical black area OB, the first substrate 1 may be provided thereon with a light-shield pattern WG, a first connection structure 120, a first conductive pad 81, and a bulk color filter 90. The first connection structure 120 may include a first connection line 121, a first connection dielectric pattern 123, and a first capping pattern 125.

A portion of the first connection line 121 may be provided on the rear surface 1b of the first substrate 1. The light-shield pattern WG may conformally cover inner walls of third and fourth trenches TR3 and TR4, while covering the rear surface 1b. The first connection line 121 may penetrate a photoelectric conversion layer 150 and the upper wiring layer 221 to connect the photoelectric conversion layer 150 to the wiring layer 200. For example, the first connection line 121 may be in contact with wiring lines of the upper wiring layer 221 and the lower wiring layer 223 and with a semiconductor pattern 13 and 15 of the pixel isolation part DTI in the photoelectric conversion layer 150. Therefore, the first connection structure 120 may be electrically connected to wiring lines in the wiring layer 200. The first connection line 121 may include a metallic material, such as tungsten. The light-shield pattern WG may block incidence of light into the optical black area OB.

The first conductive pad 81 may be provided in the third trench TR3 to fill an unoccupied portion of the third trench TR3. The first conductive pad 81 may include a metallic material, such as aluminum. The first conductive pad 81 may be connected to the semiconductor pattern 13 and 15 of FIG. 4A. A negative bias voltage may be applied through the first conductive pad 81 to the semiconductor pattern 13 and 15 of FIG. 4A. Therefore, it may be possible to prevent or reduce white spot and/or dark current.

The first connection dielectric pattern 123 may fill an unoccupied portion of the fourth trench TR4. The first connection dielectric pattern 123 may completely or partially penetrate the photoelectric conversion layer 150 and the wiring layer 200. The first capping pattern 125 may be provided on a top surface of the first connection dielectric pattern 123. The first capping pattern 125 may be provided on the first connection dielectric pattern 123.

The bulk color filter 90 may be provided on the first conductive pad 81, the light-shield pattern WG, and the first capping pattern 125. The bulk color filter 90 may cover the first conductive pad 81, the light-shield pattern WG, and the first capping pattern 125. A first protection layer 71 may be provided on and encapsulate the bulk color filter 90.

A photoelectric conversion element PD′ and a dummy element PD″ may be provided on the optical black area OB of the first substrate 1. For example, the photoelectric conversion element PD′ may be doped with impurities having the second conductivity type different from the first conductivity type. The second conductivity type may be, for example, an n-type. The photoelectric conversion element PD′ may have a similar structure to that of a photoelectric conversion element PD on the pixel array area APS, but may not execute the same operation (e.g., generation of electrical signals from received light) as that of the photoelectric conversion element PD. The dummy element PD″ may not be doped with impurities. The dummy element PD″ may generate signals that are used as information to remove subsequent process noise.

On the pad area PAD, the first substrate 1 may be provided thereon with a second connection structure 130, a second conductive pad 83, and a second protection layer 73. The second connection structure 130 may include a second connection line 131, a second connection dielectric pattern 133, and a second capping pattern 135.

The second connection line 131 may be provided on the rear surface 1b of the first substrate 1. For example, the second connection line 131 may conformally cover inner walls of fifth and sixth trenches TR5 and TR6, while covering the rear surface 1b. The second connection line 131 may penetrate the photoelectric conversion layer 150 and the upper wiring layer 221 to connect the photoelectric conversion layer 150 to the wiring layer 200. For example, the second connection line 131 may be in contact with wiring lines in the lower wiring layer 223. Therefore, the second connection structure 130 may be electrically connected to wiring lines in the wiring layer 200. The second connection line 131 may include a metallic material, such as tungsten.

The second conductive pad 83 may be provided in the fifth trench TR5 to fill an unoccupied portion of the fifth trench TR5. The second conductive pad 83 may include a metallic material, such as aluminum. The second conductive pad 83 may serve as an electrical connection path through which the image sensor 507 is connected to an external apparatus. The second connection dielectric pattern 133 may fill an unoccupied portion of the sixth trench TR6. The second connection dielectric pattern 133 may completely or partially penetrate the photoelectric conversion layer 150 and the wiring layer 200. The second capping pattern 135 may be provided on the second connection dielectric pattern 133.

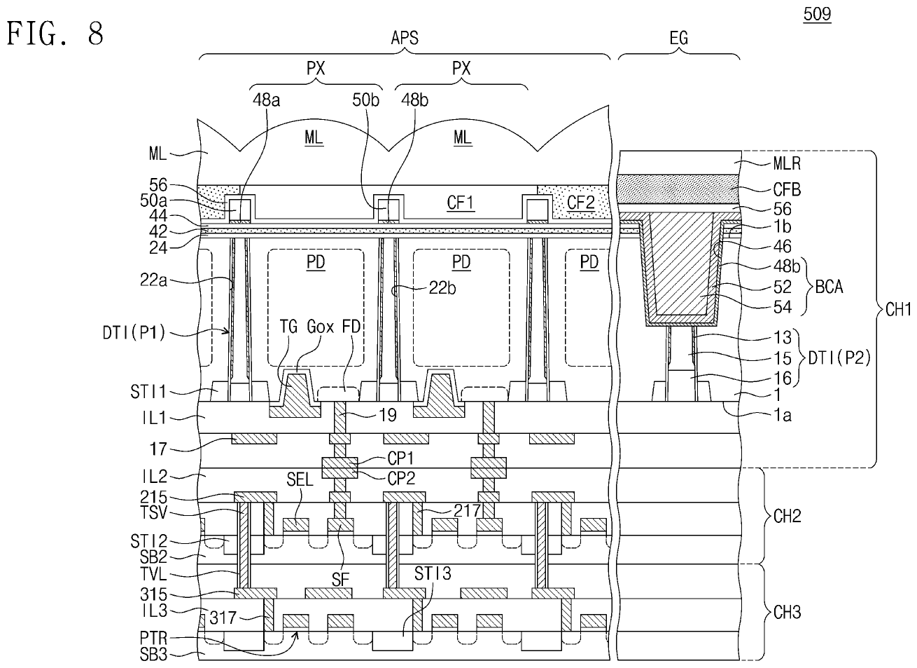

FIG. 8 illustrates a cross-sectional view showing an image sensor according to some embodiments.

Referring to FIG. 8, an image sensor 509 according to the present embodiment may have a structure in which first to third sub-chips CH1 to CH3 are sequentially bonded. The first sub-chip CH1 may have, for example, an image sensing function. The first sub-chip CH1 may be the same as or similar to that discussed with reference to FIGS. 3 to 5B.

The first sub-chip CH1 may include transfer gates TG on a front surface 1a of a first substrate 1, and may also include first interlayer dielectric layers IL1 that cover the transfer gates TG. The first substrate 1 may include a pixel array area APS and an edge area EG. The pixel array area APS may include a plurality of pixels PX. The edge area EG may correspond to a portion of the optical black area OB of FIG. 7.

The first substrate 1 may be provided therein a first device isolation part STI1 that defines active sections. The first substrate 1 may be provided therein with a pixel isolation part DTI that separates and/or limit the unit pixels PX on the pixel array area APS. The pixel isolation part DTI may extend to the edge area EG. The pixel isolation part DTI may be the same as or similar to that discussed with reference to FIGS. 3 to 5B.

The front surface 1a of the first substrate 1 may be covered with the first interlayer dielectric layers IL1. The first interlayer dielectric layers IL1 may be provided with first wiring lines 17 therebetween or therein. A floating diffusion region FD may be connected through a first contact plug 19 to the first wiring lines 17. A first conductive pad CP1 may be disposed in a lowermost first interlayer dielectric layer IL1. The first conductive pad CP1 may include copper.

On the edge area EG, a connection contact BCA may penetrate the first protection layer 44, the antireflection layer 24, and a portion of the first substrate 1 to come into contact with the semiconductor pattern 13 and 15. The connection contact BCA may be positioned in a third trench 46. The connection contact BCA may include a diffusion stop pattern 48g that conformally covers an inner sidewall and a bottom surface of the third trench 46, a first metal pattern 52 on the diffusion stop pattern 48g, and a second metal pattern 54 that fills the third trench 46. The diffusion stop pattern 48g may include, for example, titanium. The first metal pattern 52 may include, for example, tungsten. The second metal pattern 54 may include, for example, aluminum. The diffusion stop pattern 48g and the first metal pattern 52 may extend onto the first protection layer 44 to come into electrical connection with other wiring lines, vias, and/or contacts.

A second protection layer 56 may be stacked on the first protection layer 44. The second protection layer 56 may conformally cover a light-shield pattern 48a, a low-refractive pattern 50a, and the connection contact BCA.

On the edge area EG, a first optical black pattern CFB may be disposed on the second protection layer 56. The first optical black pattern CFB may include, for example, the same material as that of a blue color filter.

On the edge area EG, a lens layer residue MLR may be disposed on the first optical black pattern CFB. The lens layer residue MLR may include the same material as that of the microlenses ML.

The second sub-chip CH2 may include a second substrate SB2, selection gates SEL, source follower gates SF, and reset gates (not shown) that are disposed on the second substrate SB2, and second interlayer dielectric layers IL2 that cover the selection gates SEL, the source follower gates SF, and the reset gates. The second substrate SB2 may be provided therein with a second device isolation part STI2 that defines active sections. Second contacts 217 and second wiring lines 215 may be disposed in the second interlayer dielectric layers IL2. A second conductive pad CP2 may be disposed in an uppermost second interlayer dielectric layer IL2. The second conductive pad CP2 may include copper. The second conductive pad CP2 may be in contact with the first conductive pad CP1. The source follower gates SF may be connected to corresponding floating diffusion regions FD of the first sub-chip CH1.

The third sub-chip CH3 may include a third substrate SB3, peripheral transistors PTR disposed on the third substrate SB3, and third interlayer dielectric layers IL3 that cover the peripheral transistors PTR. The third substrate SB3 may be provided therein with a third device isolation part STI3 that defines active sections. Third contacts 317 and third wiring lines 315 may be disposed in the third interlayer dielectric layers IL3. An uppermost third interlayer dielectric layer IL3 may be in contact with the second substrate SB2. A through electrode TSV may penetrate the second interlayer dielectric layer IL2, the second device isolation part STI2, the second substrate SB2, and the third interlayer dielectric layer IL3 to thereby connect the second wiring line 215 to the third wiring line 315. A via dielectric layer TVL may surround a sidewall of the through electrode TSV. The third sub-chip CH3 may include circuits either for driving one or both of the first sub-chip CH1 and the second sub-chip CH2 or for storing electrical signals generated from one or both of the first sub-chip CH1 and the second sub-chip CH2.

An image sensor according to some embodiments may include a capping pattern in a pixel isolation part. The capping pattern may fill a void in a semiconductor pattern or a dielectric pattern to thereby protect the semiconductor pattern. Therefore, the image sensor may improve in reliability.

In a method of fabricating an image sensor, a void in a pixel isolation pattern with a capping pattern to protect a semiconductor pattern when subsequent processes are performed. Accordingly, the method of fabricating an image sensor may increase in yield.

It will be understood by one of ordinary skill in the art that variations in form and detail may be made therein without departing from the spirit and essential features of the following claims.

What is claimed is:

1. An image sensor comprising:
a substrate having a first surface and a second surface, the first surface being opposite to the second surface;
an antireflection layer disposed on the second surface of the substrate; and
a pixel isolation part disposed in the substrate, the pixel isolation part separating a plurality of pixels from each other,
wherein the plurality of pixels comprises a first pixel, a second pixel, a third pixel and a fourth pixel, all of which are arranged along a clockwise direction,
wherein the pixel isolation part comprises:
a first isolation part disposed between the first pixel and the third pixel, and
a second isolation part disposed between a first center of the first pixel and a second center of the second pixel,
wherein each of the first isolation part and the second isolation part comprises:
a semiconductor pattern that penetrates the substrate along a direction perpendicular to the first surface,
a first isolation dielectric pattern disposed between the substrate and the semiconductor pattern, and
a capping pattern in the semiconductor pattern, wherein the capping pattern is in contact with the antireflection layer.

2. The image sensor of claim 1, wherein the semiconductor pattern comprises a first semiconductor pattern and a second semiconductor pattern,
the first semiconductor pattern is between the first isolation dielectric pattern and the second semiconductor pattern,
the capping pattern is spaced apart from the first semiconductor pattern across the second semiconductor pattern, and
a top surface of the capping pattern is coplanar with the second surface of the substrate.

3. The image sensor of claim 2, wherein the capping pattern conformally covers a first inner surface of the second semiconductor pattern,
the antireflection layer includes a horizontal part and a vertical part, and
the vertical part of the antireflection layer extends into the substrate and covers a second inner surface of the capping pattern.

4. The image sensor of claim 1, further comprising an inner void in the semiconductor pattern and below the capping pattern,
wherein the inner void is at least partially surrounded by the semiconductor pattern and the capping pattern.

5. The image sensor of claim 1, wherein the capping pattern comprises at least one of silicon oxide including SiO₂, metal including W, Al, or Cu, high-k dielectrics including Al₂O₃, HfO, or TiO₂, polysilicon, or amorphous polysilicon.

6. The image sensor of claim 1, wherein the first pixel and the second pixel are disposed side by side along a first direction,
the first pixel and the third pixel are disposed in a second direction that intersects the first direction,
the first isolation part has a first width in the second direction,
the second isolation part has a second width in the first direction, and
the second width is less than the first width.

7. The image sensor of claim 1, wherein the first isolation dielectric pattern is a single layer or a multiple layer.

8. The image sensor of claim 1, wherein the pixel isolation part further comprises a third isolation part between the first pixel and the second pixel.

9. The image sensor of claim 1, wherein the capping pattern extends from the second surface toward the first surface of the substrate, and
a width of the capping pattern decreases when viewed beginning at the second surface and moving toward the first surface of the substrate.

10. An image sensor, comprising:
a substrate having a first surface and a second surface the first surface being opposite to the second surface;
an antireflection layer disposed on the second surface of the substrate; and
a pixel isolation part disposed in the substrate, the pixel isolation part separating a plurality of pixels from each other,
wherein the plurality of pixels comprises a first pixel, a second pixel, a third pixel and a fourth pixel arranged along a clockwise direction,
wherein the pixel isolation part comprises a first isolation part between a first center of the first pixel and a second center of the second pixel, and
wherein the first isolation part comprises:
a dielectric pattern that penetrates the substrate along a direction perpendicular to the first surface, wherein the dielectric pattern includes a first dielectric pattern adjacent to the second surface and a buried dielectric pattern adjacent to the first surface;
a first isolation dielectric pattern disposed between the substrate and the dielectric pattern;
a first semiconductor pattern disposed between the first isolation dielectric pattern and the first dielectric pattern; and
a capping pattern in the first dielectric pattern, wherein the capping pattern is between the antireflection layer and the first dielectric pattern.

11. The image sensor of claim 10, wherein the pixel isolation part further comprises a second isolation part disposed between the first pixel and the third pixel,
wherein the second isolation part comprises:
a semiconductor pattern of the second isolation part that penetrates the substrate along the direction perpendicular to the first surface;
a second isolation dielectric pattern between the substrate and the semiconductor pattern of the second isolation part; and
a second capping pattern in the semiconductor pattern of the second isolation part,
wherein the semiconductor pattern of the second isolation part comprises a first semiconductor pattern of the second isolation part and a second semiconductor pattern of the second isolation part,
wherein the first semiconductor pattern of the second isolation part is between the first isolation dielectric pattern and the second semiconductor pattern of the second isolation part, and
wherein the second capping pattern is between the antireflection layer and the second semiconductor pattern of the second isolation part.

12. The image sensor of claim 10, wherein the capping pattern is in contact with the antireflection layer.

13. The image sensor of claim 10, wherein the capping pattern conformally covers a first inner surface of the first dielectric pattern,
the antireflection layer includes a horizontal part and a vertical part, and
the vertical part of the antireflection layer extends into the substrate and covers a second inner surface of the capping pattern.

14. The image sensor of claim 10, further comprising an inner void in the dielectric pattern and below the capping pattern,
wherein the inner void is at least partially surrounded by the dielectric pattern and the capping pattern.

15. The image sensor of claim 10, wherein the capping pattern comprises at least one of silicon oxide including SiO₂, metal including W, Al, or Cu, high-k dielectrics including Al₂O₃, HfO, or TiO₂, polysilicon, or amorphous polysilicon.

16. The image sensor of claim 10, wherein the capping pattern is spaced apart from the first semiconductor pattern across the first dielectric pattern, and
a top surface of the capping pattern is coplanar with the second surface of the substrate.

17. A method of fabricating an image sensor, the method comprising:
preparing a substrate having a first surface and a second surface the first surface being opposite to the second surface;
forming a deep trench that extends from the first surface into the substrate;
forming a first isolation dielectric layer that covers an inner wall of the deep trench;
forming a first semiconductor pattern that conformally covers the first isolation dielectric layer in the deep trench;
forming a second semiconductor pattern that fills a portion of the deep trench, the second semiconductor pattern including a void;
forming a buried dielectric pattern that fills an occupied portion of the deep trench;
etching the second surface of the substrate to expose the void;
forming a capping pattern that fills the void; and
forming an antireflection layer on the second surface of the substrate,
wherein the capping pattern is in contact with the antireflection layer.

18. The method of claim 17, wherein the capping pattern comprises at least one of silicon oxide including SiO₂, metal including W, Al, or Cu, high-k dielectrics including Al₂O₃, HfO, or TiO₂, polysilicon, or amorphous polysilicon.

19. The method of claim 17, wherein forming the capping pattern comprises:
depositing a capping layer on the second surface of the substrate; and
performing an etching process on the capping layer.

20. The method of claim 19, wherein performing the etching process on the capping layer includes etching the capping layer until a top surface of the second semiconductor pattern is exposed.
